(19) United States
(12) Patent Application Publication
(10) Pub. No.: US 2002/0048926 A1
(43) Pub. Date: Apr. 25, 2002

(54) Method for forming a self-aligned copper capping diffusion barrier

(76) Inventor: Anthony J. Konecni, Plano, TX (US)

Correspondence Address: TEXAS INSTRUMENTS INCORPORATED, P O BOX 655474, M/S 3999, DALLAS, TX, 75265

(21) Appl. No.: 09/947,487

(22) Filed: Sep. 6, 2001

Related U.S. Application Data
(60) Provisional application No. 60/232,563, filed on Sep. 14, 2000.

(51) Int. Cl. H01L 21/4763

(52) U.S. Cl. 438/618

(57) ABSTRACT

A copper interconnect having a self-aligned aluminum barrier (124). After the copper interconnect lines (118) are formed, an aluminum layer (124) is selectively deposited over the surface of the copper interconnect lines (118), but not over the IMD (108). The aluminum barrier (124) may be converted to aluminum-oxide or aluminum-nitride.

### FIELD OF THE INVENTION

The invention is generally related to the field of forming interconnect layers in integrated circuits.

### BACKGROUND OF THE INVENTION

As the density of semiconductor devices increases, the demands on interconnect layers for connecting the semiconductor devices to each other also increases. Therefore, there is a desire to switch from the traditional aluminum metal interconnects to copper interconnects. Unfortunately, suitable copper etches for a semiconductor fabrication environment are not readily available. To overcome the copper etch problem, damascene processes have been developed.

In a conventional interconnect process, the aluminum (and any barrier metals) are deposited, patterned, and etched to form the interconnect lines. Then, an interlevel dielectric (ILD) is deposited and planarized. In a damascene process the intrametal dielectric (IMD) 16 is formed first. The IMD 16 is then patterned and etched. The barrier layer 14 and a copper seed layer are then deposited over the structure. The copper layer is then formed using the seed layer over the entire structure. The copper is then chemically-mechanically polished (CMP'd to remove the copper from over the IMD 16, leaving copper interconnect lines 18 embedded in the IMD as show in FIG. 1A. A metal etch is thereby avoided.

Next, a silicon nitride layer 20 is deposited over the copper 18 and IMD 16, as shown in FIG. 1B. Copper must be surrounded by a barrier to prevent it from diffusing into the surrounding dielectric. An ILD 22 is then formed over the silicon nitride layer 20. Unfortunately, the silicon nitride layer 20 has a high dielectric constant and thus increases the total dielectric constant for the ILD/IMD layers. The higher dielectric constant results in an increased line-to-line capacitance. In addition, the poor interface between silicon nitride (a dielectric) and copper (a conductor) results in poor adhesion and poor electromigration (copper electromigration via interface diffusion).

### SUMMARY OF THE INVENTION

A structure and method for forming a metal interconnect is disclosed herein. After the metal interconnect lines are formed, aluminum is selectively deposited over the surface of the metal interconnect lines but not over the interlevel dielectric. In one embodiment of the invention, the aluminum is then oxidized to form the barrier layer. In another embodiment, the aluminum is converted to aluminum-nitride to form the barrier layer.

An advantage of the invention is providing a barrier for a metal interconnect only over the metal to avoid placing a high dielectric constant layer in the dielectric stack.

This and other advantages will be apparent to those of ordinary skill in the art having reference to the specification in conjunction with the drawings.

### BRIEF DESCRIPTION OF THE DRAWINGS

In the drawings:

FIGS. 1A-1B are cross-sectional diagrams of a prior art dual damascene process using a silicon-nitride barrier at various stages of fabrication.

FIG. 2 is a cross-sectional diagram of an interconnect line having an aluminum barrier layer according to the invention;

FIGS. 3A-3C are cross-sectional diagrams of the interconnect line of FIG. 2 at various stages of fabrication;

FIG. 4 is a cross-sectional diagram of the interconnect line of FIG. 3 with an aluminum-oxide barrier; and

FIG. 5 is a cross-sectional diagram of the interconnect line of FIG. 3 with an aluminum-nitride barrier.

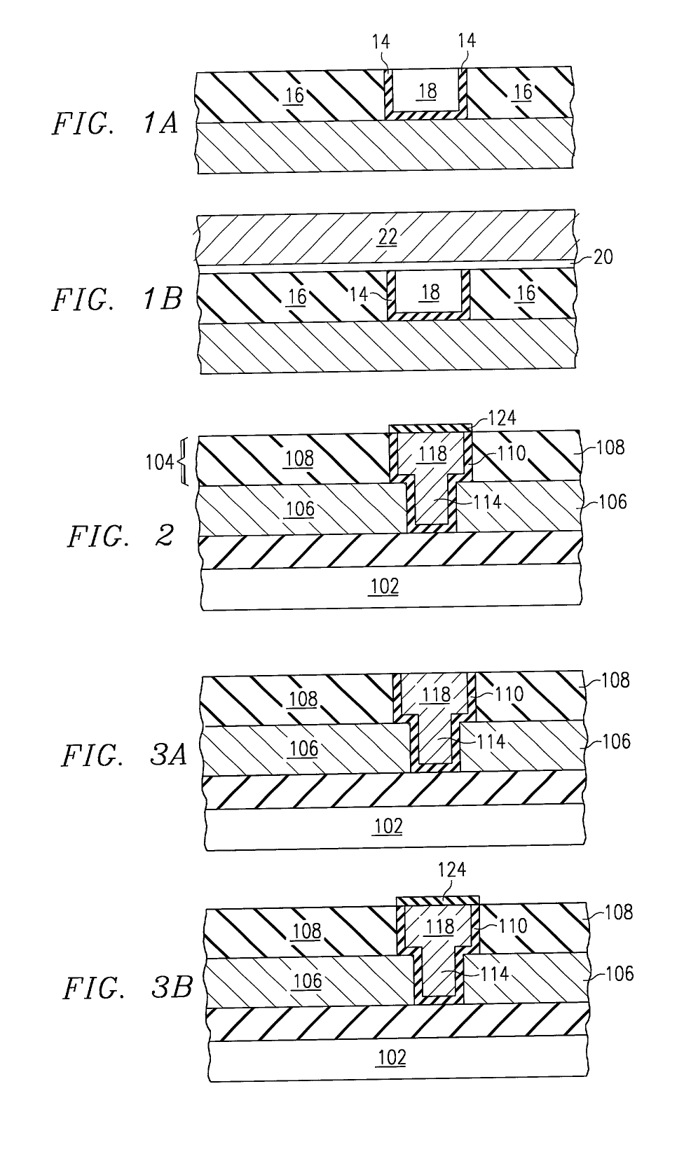

### DETAILED DESCRIPTION OF THE EMBODIMENTS

The invention will now be described in conjunction with a dual damascene copper interconnect process. It will be apparent to those of ordinary skill in the art that the invention may be applied to other copper interconnect processes as well.

One approach for eliminating the silicon nitride top barrier for copper interconnects is dope the copper with aluminum. An aluminum barrier is formed via a secondary diffusion anneal to remove the aluminum dopants out of the copper. However, with this approach, there is a significant risk of increased line resistance due to aluminum impurities remaining in the copper.

To avoid this difficulty, the invention uses a selectively deposited aluminum over the exposed copper surface to form an aluminum barrier. Equipment for selective CVD of aluminum is commercially available. Because the aluminum is only deposited over the exposed copper, the formation of a higher dielectric constant material between the ILD and IMD layers is avoided.

A metal interconnect layer 104 according to the invention is shown in FIG. 2. Metal interconnect layer 104 is located over a semiconductor body 102. Multiple metal interconnect layers are typically included in a given integrated circuit. Metal interconnect layer 104 may be part of the second or any subsequent metal interconnect layer. Metal interconnect layer 104 comprises a copper interconnect line 118 is embedded in an intrametal dielectric (IMD) 108. IMD 108 may, for example, comprise FSG (fluorine-doped silicate glass). Other suitable materials will be apparent to those of ordinary skill in the art. For example, PSG (phosphorous doped silicate glass), BPSG (boron and phosphorous doped silicate glass), PETEOS (plasma enhanced tetraethyoxysilane), HDP (high-density plasma) oxide, HSQ (hydrogen silsesquioxane), or combinations thereof may be used for IMD 108.

Copper interconnect line 118 comprises an underlying diffusion barrier 110. Diffusion barrier 110 may, for example, comprise Ta/TaN. Other suitable diffusion barriers and combinations of diffusion barriers are known in the art.

A conductive via 114 extends below copper interconnect line 118 through interlevel dielectric (ILD) 106. Via 114 provides connection to lower interconnect levels, transistors, and other components.

The invention uses a diffusion barrier 124 comprising an aluminum material over the copper interconnect line 118, as shown in FIG. 2. The diffusion barrier 124 is self-aligned to the copper interconnect. Thus, there is no adverse impact on the line-to-line capacitance as in the prior art silicon nitride barrier. Diffusion barrier 124 may, for example, comprise aluminum, aluminum oxide, or aluminum nitride. The thickness of diffusion barrier 124 may be in the range of 50-500 Å.

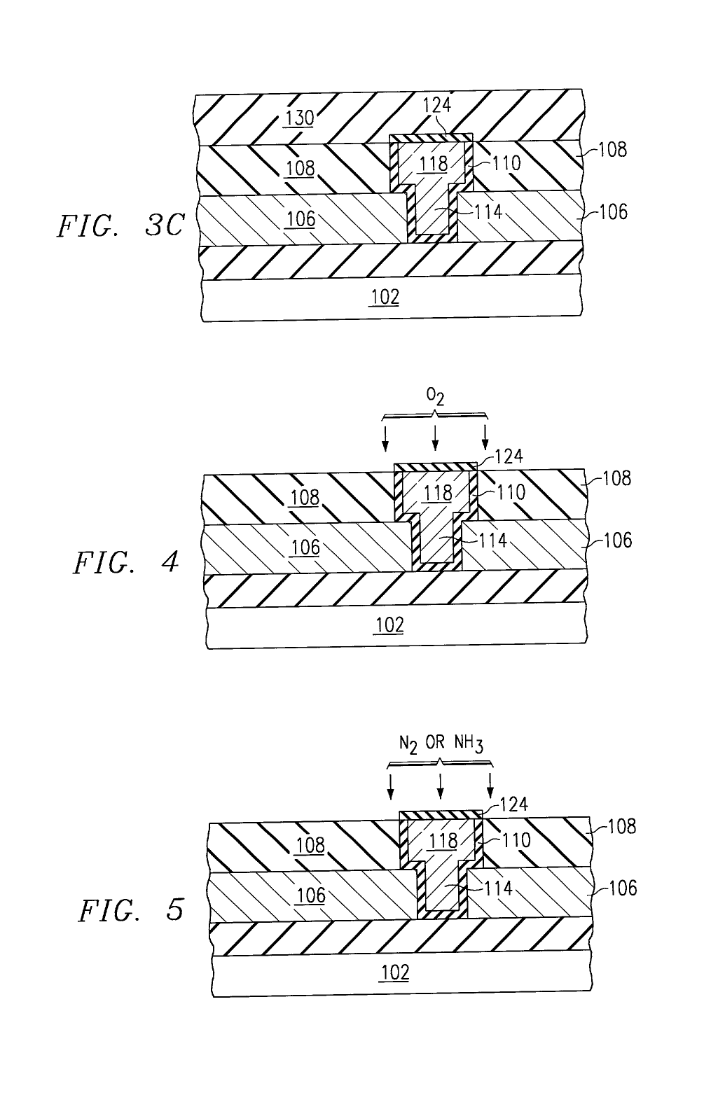

A method for forming the barrier layer 124 will now be discussed with reference to FIGS. 3A-3C. As shown in FIG. 3A, the semiconductor body 102 is processed through the formation of ILD 106, IMD 108, copper interconnect line 118, and conductive via 114. Methods for forming the structure of FIG. 3A are known in the art. Semiconductor body 102 will typically contain transistors and other devices formed in a surface of a substrate or epitaxial layer as is known in the art. IMD 108 and copper interconnect line 118 may be part of one of several interconnect layers formed as part semiconductor body 102.

FIG. 3A illustrates a dual damascene approach to form copper interconnect line 118 and conductive via 114. In a dual damascene approach, the interconnect lines and conductive vias are formed at the same step. First, the ILD 106 and IMD 108 are both formed. Then, the trench (for the interconnect line) and via are formed. The trench is etched in the IMD 108 and the via is etched in the ILD 106. The barrier 110 is deposited in the trench and via. Then, both the trench and via are filled with copper typically using an electroplating process. The copper is then chemically-mechanically polished (CMP'd) until it is roughly planar with the surface of the IMD 108.

Following the copper CMP and clean-up of the structure of FIG. 3A, a plasma pre-treatment may be performed to clean any native oxide from the exposed copper surfaces. Then, referring to FIG. 3B, aluminum 124 is selectively deposited over the exposed copper of copper interconnect line 118. Aluminum 124 is not formed over IMD 108. The selective deposition of aluminum is performed in the same chamber as the plasma pre-treatment to avoid the regrowth of the native oxide. The thickness of aluminum 124 may be on the order of 50-500 Å.

Tools for selective aluminum chemical vapor deposition (CVD) are commercially available. An exemplary process uses a temperature on the order of 260° C., a pressure on the order of 2 torr, a gas flow of DMAH (DiMethyl Aluminum Hydride) of 200 sccm and a gas flow of Ar of 200 sccm.

If an aluminum oxide barrier is desired instead of aluminum, aluminum barrier 124 may be subjected to an oxidation step to convert the aluminum (or at least a portion of the aluminum) to aluminum oxide. Aluminum oxide for barrier 124 is shown in FIG. 4. For example, an O₂ plasma using a power in the range of 100-100 W, a pressure in the range of 5 torr-50 torr and a flow rate in the range of 100-3000 sccm could be used. Alternative processes, such as an O₂ anneal (e.g., 25°-200° C.) or ambient exposure (for uncontrolled formation), will be apparent to those of ordinary skill in the art.

If an aluminum nitride barrier is desired, the aluminum or aluminum oxide of barrier 124 may be converted to aluminum nitride. Aluminum nitride barrier 124 is shown in FIG. 5. Several methods for converting aluminum or aluminum oxide to aluminum nitride are available. For example, barrier 124 may be subjected to an anneal in a nitrogen ambient or plasma nitridation (plasma and a nitrogen-containing ambient).

The temperature of the optional nitrogen anneal may be in the range of 200° C.-500° C. The duration of the nitrogen anneal is on the order of 30 minutes in a furnace or 1 minute in a RTP (rapid thermal processing) chamber.

After the selective aluminum deposition (and any optional conversion to aluminum oxide or aluminum-nitride), ILD 130 may be formed, as shown in FIG. 3C. Materials such as those described above for ILD 106 may be used. Processing then continues with the formation of any additional metal interconnect levels, protective overcoats, and packaging. The above process may be repeated for each metal interconnect level.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. For example, the invention is not limited to a dual damascene copper interconnect process. The selective aluminum deposition may be applied to any exposed copper to form a barrier. It is therefore intended that the appended claims encompass any such modifications or embodiments.

In the claims:

1. A method of forming an integrated circuit, comprising the steps of:
forming a copper structure over a semiconductor body,
selectively depositing an aluminum-containing layer over said copper structure to form a barrier layer for said copper structure.

2. The method of claim 1, further comprising the step of oxidizing said aluminum-containing layer.

3. The method of claim 1, further comprising the step of nitridizing said aluminum-containing layer.

4. A method of forming an integrated circuit, comprising the steps of:
forming a copper interconnect layer over a semiconductor body, said copper interconnect layer having an exposed copper surface;
selectively depositing an aluminum-containing layer on said exposed copper surface.

5. The method of claim 4, further comprising the step of oxidizing said aluminum-containing layer.

6. The method of claim 4, further comprising the step of converting said aluminum-containing layer to aluminum-nitride.

7. The method of claim 4, further comprising the step of forming a first dielectric layer over said semiconductor body, wherein said copper interconnect layer is embedded in said first dielectric layer and wherein said selectively deposited aluminum-containing layer is self-aligned to said copper interconnect layer.

8. The method of claim 4, further comprising the step of forming a second dielectric layer over said aluminum-containing layer.

9. An integrated circuit, comprising:
an intrametal dielectric layer;
a copper interconnect line embedded in said intrametal dielectric layer; and
an aluminum-containing layer on said copper interconnect line, said aluminum-containing layer being self-aligned to said copper interconnect line.

10. The integrated circuit of claim 9, wherein said aluminum-containing layer comprises aluminum oxide.

11. The integrated circuit of claim 9, wherein said aluminum-containing layer comprises aluminum-nitride.
